(19) United States
(12) Patent Application Publication
(10) Pub. No.: US 2009/0072838 A1
(43) Pub. Date: Mar. 19, 2009

(54) Multi-port switching apparatus, device testing system and method of testing therefor

(76) Inventors: Ewan William Shepherd, Torphichen (GB); Alan Thomas Potter, Rumford (GB)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/901,111

(22) Filed: Sep. 14, 2007

(51) Int. Cl. H01H 67/00; G01R 31/02

(52) U.S. Cl. 324/537; 324/555

(57) ABSTRACT

A multi-port switching apparatus (104) comprises a first port (204) and a second port (210) for coupling respectively to a device under test (300). The apparatus (104) also comprises an analyser port (108) for coupling to a signal analyser (102) and a switching unit (200) coupled to the first port (204), the second port (210) and the analyser port (108). The switching unit (200) is controllable so as to couple, when in use, the analyser port (108) to the first port (204) for a first duration. After the first duration, the analyser port (108) is coupled to the second port (210) substantially instead of the first port (204) for a second duration.

### TECHNICAL FIELD

The present invention relates to a multi-port switching apparatus of the type that, for example, is used to couple a signal analyser to multiple ports associated with a device under test, such as a Multiple Input Multiple Output (MIMO) communications device. The present invention also relates to a multi-port device testing system of the type that, for example, comprises a signal analyser coupled to multiple ports associated with a device under test, such as a MIMO communications device. The present invention further relates to a method of testing of the type that, for example, is used to test operation of a multi-port device under test, such as a MIMO communications device.

### BACKGROUND ART

In the field of wireless communications, MIMO options are included in many radio communications standards. In particular, the Institute of Electrical and Electronic Engineers (IEEE) 802.11n Wireless Local Area Network (WLAN) standard includes MIMO operation. The benefits of MIMO WLAN devices are clear, namely: significant increases in data rate and/or range without increasing bandwidth or output power.

To achieve MIMO capability, however, it is necessary for a wireless communications device implementing MIMO functionality to have multiple transmitters and receivers at each end of a communications link. In addition to the cost and complexity associated with such products, the cost of manufacture and final test can be multiplied. In this respect, performance of the transmitters and receivers in the MIMO capable wireless communications device have to be significantly better than the performance of existing devices, for example, in the context of WLANs: Orthogonal Frequency-Division Multiplex (OFDM) WLAN devices manufactured to support the IEEE 802.11g standard.

The new performance requirements are accompanied by new challenges for manufacturing test systems in order to ensure that products manufactured meet quality and performance goals of the manufacturer. Since cost of testing is directly proportional to test time, a test methodology should ideally be selected that minimises test time, whilst maintaining quality, accuracy and repeatability.

Typically, there are four “popular” different known types of test configuration employed when testing MIMO capable devices, though others may exist for different devices and/or applications for such devices. A first, legacy, configuration employing a so-called “Golden Radio” generator, a spectrum analyser, a signal generator and a power meter. A second configuration employs a multi-channel, One-Box, Tester (OBT) or multiple synchronised OBTs. A third configuration employs a single-channel OBT and a Golden Radio generator, whilst a fourth configuration simply employs a single-channel OBT alone.

The legacy configuration was initially employed due to a lack availability of dedicated test instruments, but suffered from a number of drawbacks, including: poor transmitter test coverage and support of Golden Radio generators. In relation to the second configuration employing either multiple channel OBTs or multiple OBTs, although this configuration offers true MIMO testing, the higher cost of the equipment involved generally restricts use of this configuration to a Research & Development laboratory environment and not a mass-manufacturing environment. Indeed, for example, to test a three-channel Device Under Test (DUT) requires a three-channel generator and analyser or three OBTs connected to allow appropriate triggering of the tests to be performed. Such expense is unacceptable to some MIMO-capable device manufacturers, for example WLAN manufacturers, where the benefits of testing using this configuration do not warrant the additional cost.

Use of the third configuration, whilst providing some advantages, still fails to address how to measure MIMO channels using a single-channel OBT. Whilst the fourth configuration employing a single-channel OBT is the simplest approach, testing time and channel coverage are inadequate.

### DISCLOSURE OF INVENTION

According to a first aspect of the present invention, there is provided a multi-port switching apparatus, the apparatus comprising: a first port for coupling to a device under test; a second port for coupling to the device under test; an analyser port for coupling to a signal analyser; a switching unit coupled to the first port, the second port and the analyser port; wherein the switching unit is controllable so as to couple, when in use, the analyser port to the first port for a first duration and thereafter couple the analyser port to the second port substantially instead of the first port for a second duration.

The switching unit may be arrange to receive, when in use, a control signal, the switching unit changing coupling from between the analyser port and the first port to between the analyser port and the second port in response to the control signal.

The switching unit may be arranged, when in use, to decouple the analyser port from the first port before subsequently coupling the analyser port to the second port.

The apparatus may further comprise a trigger input for receiving a trigger derived from the device under test.

The apparatus may further comprise a first input port for receiving a first transmitted input signal; and a second input port for receiving a second transmitted input signal.

The apparatus may further comprise a processing resource coupled to the analyser port; wherein the processing resource is arranged, when in use, to receive a first input signal via the first port and the switching unit and sequentially a second input signal via the second port and the switching unit thereafter.

The processing resource may support signal analysis so as to serve, when in use, as the signal analyser.

The processing resource may be further arranged, when in use, to arrange temporally the first and second input signals. The temporal arrangement of the first and second input signals may be alignment of the first and second signals in time so as to emulate substantially simultaneous receipt of the first and second signals in parallel.

According to a second aspect of the present invention, there is provided a port adaptor apparatus comprising the multi-port switching apparatus as set forth above in relation to the first aspect of the invention.

According to a third aspect of the present invention, there is provided a multi-port device testing system comprising: the multi-port switching apparatus as set forth above in relation to the first aspect of the invention; and the signal analyser coupled the analyser port of the multi-port switching apparatus.

The signal analyser may comprise: a processing resource coupled to the analyser port; wherein the processing resource is arranged, when in use, to receive a first input signal via the first port and the switching unit and sequentially a second input signal via the second port and the switching unit thereafter. The processing resource is further arranged, when in use, to arrange temporally the first and second input signals. The temporal arrangement of the first and second input signals is alignment of the first and second signals in time so as to emulate substantially simultaneous receipt of the first and second signals in parallel.

The system may further comprise a trigger module coupled to the device under test and/or the signal analyser for providing a triggering signal to the processing resource and the device under test.

The system may further comprise a reference signal generator coupled to the first input port. The second input port may be coupled, when in use, to the reference signal generator. The reference signal generator may be a golden radio device.

According to a fourth aspect of the present invention, there is provided a method of testing a multi-port device under test, the method comprising: receiving a first input signal at a common port via a first port over a first duration; switching so as to receive a second input signal at the common port via a second port over a second duration; and temporally arranging the first input signal and the second input signal.

The method may further comprise: temporally arranging the first input signal and the second input signal in time so that the first and second input signals are arranged in time so as to emulate substantially simultaneous receipt of the first and second input signals in parallel.

According to a fifth aspect of the present invention, there is provided a computer program element comprising computer program code means to make a computer execute the method as set forth above in relation to the fourth aspect of the invention.

The computer program element may be embodied on a computer readable medium.

It is thus possible to provide an apparatus, system and method that enable multiple channel testing of a DUT without the additional expense or complexity of prior solutions. In this respect, switching of the apparatus is sufficiently fast to maintain test time without providing multiple parallel transmitters and receivers in the test instrument. Additionally, transmit failure mechanisms, for example: channel isolation and single, or MIMO, Error Vector Magnitudes (EVMs) can be measured and isolated. The apparatus, system and method also support use of reference signal generators, for example so-called Golden Radio support, as well as use of external channel simulators.

### BRIEF DESCRIPTION OF DRAWINGS

At least one embodiment of the invention will now be described, by way of example only, with reference to the accompanying drawings, in which:

FIG. 1 is a schematic diagram of a testing system constituting an embodiment of the invention;

FIG. 2 is an apparatus constituting another embodiment of the invention used in the system of FIG. 1;

FIG. 3 is a schematic diagram of the system of FIG. 1 employing channel simulators and Golden Radio;

FIG. 4 is a flow diagram of a method constituting a further embodiment of the invention; and

FIG. 5 is a schematic diagram of signal processing according to the embodiment of FIG. 4.

### DETAILED DESCRIPTION

Throughout the following description identical reference numerals will be used to identify like parts.

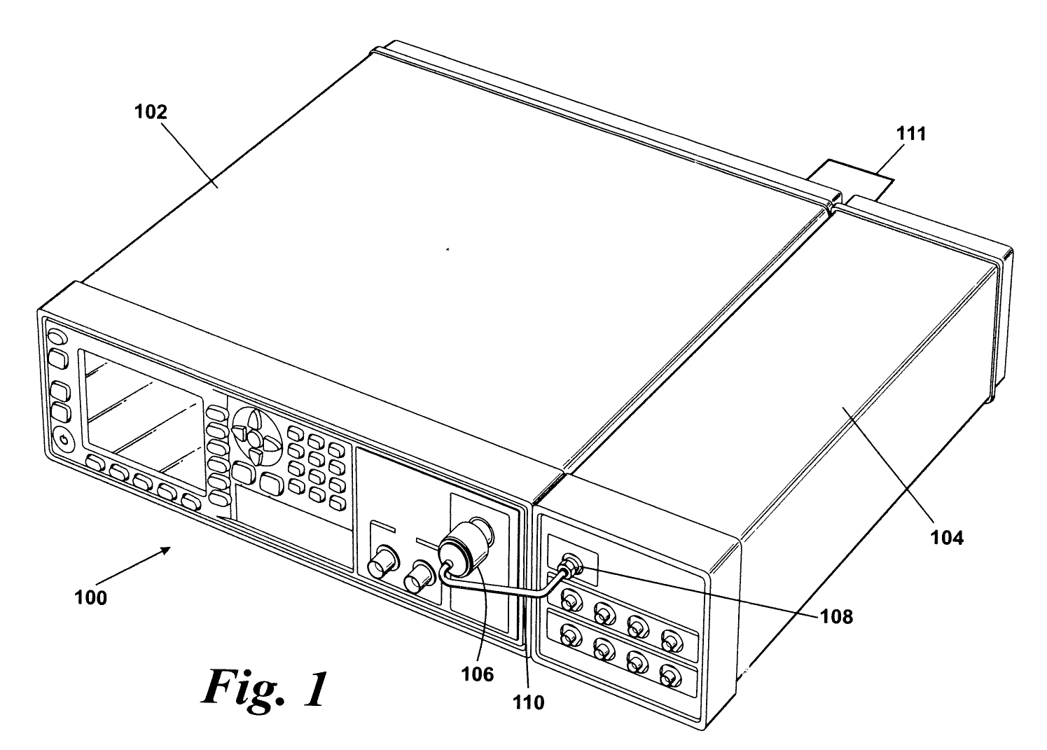

Referring to FIG. 1, a MIMO testing system 100 comprises a signal analyser 102, for example an N4010A Wireless Connectivity Test Set available from Agilent Technologies, Inc. The signal analyser 102 is loaded with appropriate software, for example 89061A Vector Signal Analysis (VSA) software also available from Agilent Technologies, Inc, but suitably altered to implement the method described herein. Although described as a “signal analyser”, the signal analyser 102 is, in this example, capable of generating signals as well. The testing system 100 also comprises a multi-port switching apparatus 104, for example, a multi-port adapter, such as an N4011A MIMO/Multi-port adapter available from Agilent Technologies, Inc., the multi-port switching apparatus 104 being coupled to the signal analyser 102.

A Radio Frequency (RF) Input/Output (I/O) port 106 of the signal analyser 102 is coupled to an RF I/O port 108 of the multi-port switching apparatus 104 via an RF patch cable 110 for carrying RF signals from the RF I/O port 108 of the multi-port switching apparatus 104 during signal analysis and in a reverse direction during signal generation by the signal analyser 102. Although not shown in FIG. 1, the signal analyser 102 comprises a processing resource, for example a microprocessor and a control interface, the control interface being coupled to a first control port (not shown) located at the rear of the signal analyser 102. A control cable 111 couples the control interface to a second control port (not shown) located at the rear of the multi-port switching apparatus 104. Additionally, the multi-part switching apparatus 104 can comprise a processing device contributing to the processing resource. Indeed, although a specific signal analyser unit is employed in this example, the term “signal analyser” should be understood to embrace the functional nature of signal analysis and so such functionality can, for example be implemented as a separate module, such as a circuit with software, or integrated into the multi-port switching apparatus 104.

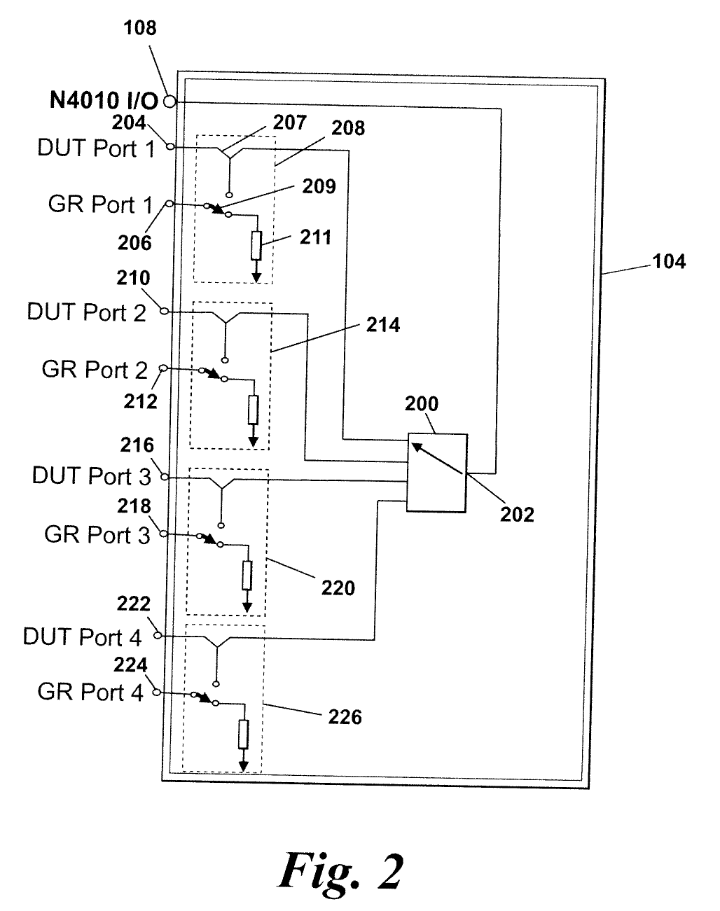

Turning to FIG. 2, the RF I/O port 108 of the multi-port switching apparatus 104 is coupled to a switching unit 200 via an analyser port 202 thereof. The multi-port switching apparatus 104 also comprises a first DUT port 204 and a first Golden Radio (GR) port 206 coupled to the switching unit 200 via a first switching module 208, the switching module 208 comprising a power splitter/combiner 207 having a first input coupled to the first DUT analyser port 202 and a second input coupled to a switch 209, the switch 209 being capable of switching the first GR port 206 between the second input of the power splitter/combiner 207 and, in this example, a 50Ω load 211. An output of the power splitter/combiner 207 is coupled to the switching unit 200. A second DUT port 210 and a second GR port 212 are coupled to the switching unit 200 via a second switching module 214. A third DUT port 216 and a third GR port 218 are coupled to the switching unit 200 via a third switching module 220. Finally, in this example, a fourth DUT port 222 and a fourth GR port 224 are coupled to the switching unit 200 via a fourth switching module 226. The structure of the second, third and fourth switching modules 214 is the same as that of the first switching module 208 and so, for the sake of conciseness, will not be repeated herein.

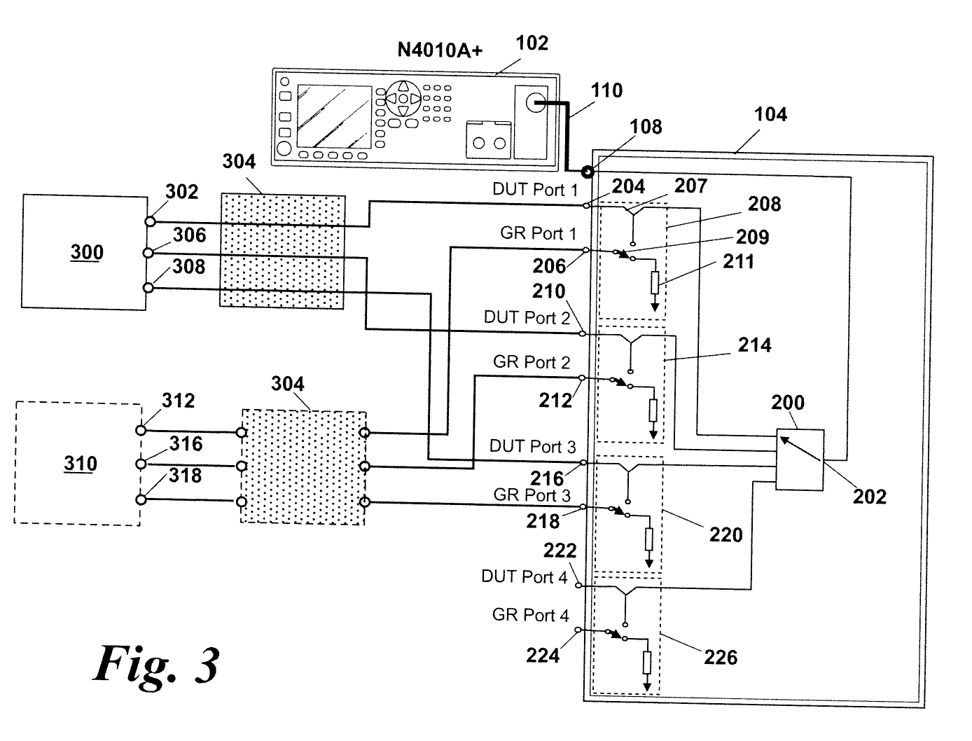

Referring to FIG. 3, a test setup comprises coupling a DUT 300 to the multi-port switching apparatus 104. In this example, the DUT 300 is a MIMO wireless access point supporting a WLAN. The DUT 300 supports 3 channels. A first probe port 302 associated with a first MIMO channel is coupled to the first DUT port 204 via a channel emulator 304, the channel emulator 304 being any suitable apparatus capable of emulating conditions in, in this example, a number of RF channels. A second probe port 306 associated with a second MIMO channel is coupled to the second DUT port 210 via the channel emulator 304, and a third probe port 308 associated with a third MIMO channel is coupled to the third DUT port 216 via the channel emulator 304. In this example, the fourth DUT port 222 is not required.

For tests requiring the use of Golden Radio, the channel emulator 304 is optionally disconnected from the probe ports 302, 306, 308 of the DUT 300 and the DUT ports 204, 210, 216 and a GR generator 310 is coupled to the multi-port switching apparatus 104 via the channel emulator 304 as follows. A first output port 312 of the GR generator 310 is coupled to the first GR port 206 of the multi-port switching apparatus 104 via the channel emulator 304. A second output port 316 of the GR generator 310 is coupled to the second GR port 212 via the channel emulator 304, and a third output port 318 of the GR generator 310 is coupled to the third GR port 218 via the channel emulator 304. In this example, the fourth GR port 224 is not required as the DUT 300 only supports three channels. Although in the above example, the channel emulator 304 has been re-connected between the GR generator 310 and the multi-port switching apparatus 104 in order to achieve a relatively direct connection between the DUT 300 and the multi-port switching apparatus 104, the connectivity between the channel emulator 304 and the multi-port switching apparatus 104 and the DUT 300 can remain unchanged for such tests involving Golden Radio, and the GR generator 310 can simply be coupled to the relevant ports of the multi-port switching apparatus 104 without the channel emulator 304 in-between.

The first, second and third probe ports 302, 306, 308 are provided in order to enable testing of transmitters associated with the first, second and third channels, respectively.

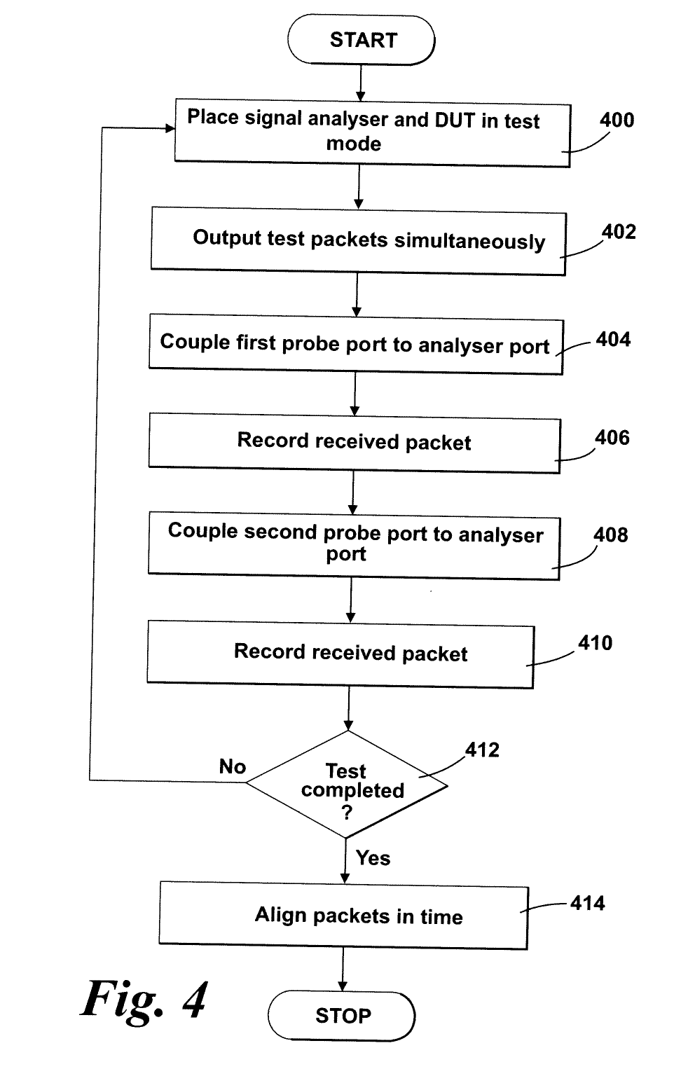

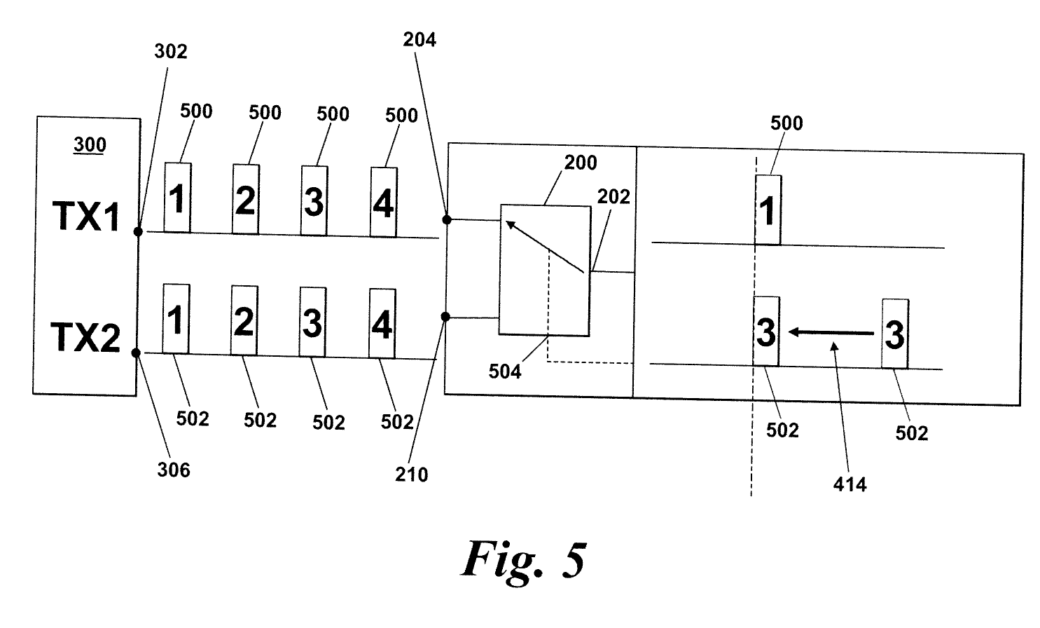

Operation of the above system will now be described, for the sake of simplicity and clarity of understanding, in the context of testing the first and second channels of the DUT 300. However, the skilled person will appreciate that the following test method can be extended to testing three or more channels if the DUT 300 is so equipped. In operation (FIGS. 4 and 5), the signal analyser 102 and the DUT 300 are both placed in respective test modes (Step 400). The transmitters (not shown) associated with the first and second channels begin transmitting data in accordance with the test mode.

In this example, a datagram is repeatedly transmitted using each channel of the DUT 300 according to a communications standard supporting MIMO, for example IEEE 802.11n. Consequently, the datagram is divided into packets, each channel of the DUT 300 being assigned one of the packets for repeated transmission. In this example, the datagram is divided into two packets, a first packet being transmitted over the first channel and a second packet being transmitted over a second channel. As a result of the above regime, a first digital output signal is output at the first probe port 302, the first digital output signal corresponding to a repeating series of, in this example, identical time-separated data packets comprising repetitions of the first data packet 500 (Step 402). Similarly, a second digital output signal is output at the second probe port 306, the second output digital signal corresponding to a repeating series of data packets comprising repetitions of the second data packet 502 (Step 402).

In accordance with the altered VSA software mentioned above, the processing resource of the signal analyser 102 sends a control signal to the switching unit 200 via the control cable 111 and a control input 504 of the switching unit 200 (coupled to the second control port) in order to couple (Step 404) the first probe port 302 to the analyser port 202 via the first DUT port 204. The signal analyser 102 then receives the first data packet 500 and stores (Step 406) the first data packet 500 in a capture memory (not shown) of the signal analyser 102. Upon determination that the first data packet 500 has been received by the signal analyser 102, the processing resource instructs the switching unit 200 to switch (Step 408) so that the first DUT port 204 is no longer coupled to the analyser port 202 and, instead, the second probe port 306 is coupled to the analyser port 202 via the second DUT port 210. A number of techniques can be employed by the signal analyser 102, to determine receipt of a given packet, for example: decoding received packets, observing RF signal levels to identify the RF signal level rising above and staying above a threshold level, or providing the signal analyser 102 with an expected packet duration in advance.

The signal analyser 102 then receives a second transmission of the second data packet 502, receipt of a first transmission of the second data packet 502 having been missed during the switching process of the switching unit 200. The analyser 102 then stores (Step 410) the second data packet 502 in the capture memory (not shown) of the signal analyser 102. The signal analyser 102 then determines whether the test has been completed (Step 412). If the test is not deemed completed, the above steps are repeated (Steps 408 to 410), but in respect of other channels and hence subsequent port numbers. However, in this example, the test is deemed completed and the signal analyser 102 then aligns (Step 414) the first and third data packets 500, 504 in time so as to emulate simultaneous receipt of the first and third packets 500, 504. The alignment is performed by time-shifting the third data packet 504 in memory so that it begins at the same point in time as the first data packet 500. However, the skilled person will appreciate that other alignment techniques can be employed, for example time-shifting the first data packet 500 into alignment instead of the third data packet 504. The signal analyser 102 then makes one or more measurements depending upon diagnostic information required in relation to operation of the DUT 300, for example: Error Vector Measurement (EVM), IQ Offset, frequency accuracy, symbol clock rate frequency accuracy, channel response, channel condition numbers. Of course, the skilled person will appreciate that other measurements can be made.

When received data packets are time-shifted, delay information is lost. However, a trigger signal can be derived from the DUT 300 and provided at a trigger input (not shown) of the signal analyser 102. Consequently, capture of the data packets at different points in time by the signal analyser 102 can be triggered. Alternatively, a separate trigger device (not shown) can be coupled both the DUT 300 if appropriately provisioned with a trigger input and the signal analyser 102. The DUT 300 and the signal analyser 102 can then be repeatedly triggered substantially simultaneously, thereby enabling recovery of delay information associated with a communications channel.

Although the above example has been described in the context of testing transmitters of the DUT 300, the skilled person should appreciate that the receivers can be tested in a number of ways. Firstly, the software of the DUT 300 can be augmented so as to provide the above packet capture and alignment technique when in the test mode. In such an embodiment, the probe ports of the DUT 300 are analogous to the DUT ports of the multi-port switching apparatus 104. Consequently, an RF signal source (not shown) within the signal analyser 102 sequentially generates, in this example, packets for receipt by the respective receivers of the DUT 300. Switching unit 200 is controlled so as to output each generated packet in sequence on the correct receive channel for which the packet was generated. The augmented software also calculates MIMO measurements based upon the received packets. Alternatively or additionally, the augmented software of the DUT 300 can be arranged to output data to be fed back to the signal analyser 102 from an Intermediate Frequency (IF) or baseband frequency from each MIMO channel of the DUT 300. For example, the digital outputs of Analogue-to-Digital Converters (ADCs) of the DUT 300 can be fed back to the signal analyser 102 where the above alignment technique is applied to the raw data that has been fed back.

Although the above embodiments have been described in the context of packet communications, it should be appreciated that the term “packet” can refer to a Protocol Data Unit (PDU) that can be used in relation to the above embodiments and vice versa. Further, other types of PDUs can be employed, for example: datagrams, frames, and cells and so these terms should be understood to be interchangeable.

Although the above examples have been described in the context of WLAN and, particularly the IEEE 802.11n standard, the skilled person will appreciate that the above-described techniques can be applied to any other MIMO-capable device, whether wireless or not.

Alternative embodiments of the invention can be implemented as a computer program product for use with a computer system, the computer program product being, for example, a series of computer instructions stored on a tangible data recording medium, such as a diskette, CD-ROM, ROM, or fixed disk, or embodied in a computer data signal, the signal being transmitted over a tangible medium or a wireless medium, for example, microwave or infrared. The series of computer instructions can constitute all or part of the functionality described above, and can also be stored in any memory device, volatile or non-volatile, such as semiconductor, magnetic, optical or other memory device.

What is claimed is:

1. A multi-port switching apparatus, the apparatus comprising:
a first port for coupling to a device under test;
a second port for coupling to the device under test;
an analyser port for coupling to a signal analyser;
a switching unit coupled to the first port, the second port and the analyser port; wherein
the switching unit is controllable so as to couple, when in use, the analyser port to the first port for a first duration and thereafter couple the analyser port to the second port substantially instead of the first port for a second duration.

2. An apparatus according to claim 1, wherein the switching unit is arrange to receive, when in use, a control signal, the switching unit changing coupling from between the analyser port and the first port to between the analyser port and the second port in response to the control signal.

3. An apparatus according to claim 1, wherein the switching unit is arranged, when in use, to decouple the analyser port from the first port before subsequently coupling the analyser port to the second port.

4. An apparatus according to claim 1, further comprising:
a trigger input for receiving a trigger derived from the device under test.

5. An apparatus according to claim 1, further comprising:
a first input port for receiving a first transmitted input signal; and
a second input port for receiving a second transmitted input signal.

6. An apparatus according to claim 1, further comprising:
a processing resource coupled to the analyser port; wherein the processing resource is arranged, when in use, to receive a first input signal via the first port and the switching unit and sequentially a second input signal via the second port and the switching unit thereafter.

7. An apparatus according to claim 6, wherein the processing resource is further arranged, when in use, to arrange temporally the first and second input signals.

8. An apparatus according to claim 7, wherein the temporal arrangement of the first and second input signals is alignment of the first and second signals in time so as to emulate substantially simultaneous receipt of the first and second signals in parallel.

9. A port adaptor apparatus comprising the multi-port switching apparatus according to claim 1.

10. A multi-port device testing system comprising:
the multi-port switching apparatus according to claim 1; wherein
the signal analyser is coupled to the analyser port of the multi-port switching apparatus.

11. A system according to claim 10, wherein the signal analyser comprises:
a processing resource coupled to the analyser port; wherein the processing resource is arranged, when in use, to receive a first input signal via the first port and the switching unit and sequentially a second input signal via the second port and the switching unit thereafter.

12. A system according to claim 11, wherein the processing resource is further arranged, when in use, to arrange temporally the first and second input signals.

13. A system according to claim 12, wherein the temporal arrangement of the first and second input signals is alignment of the first and second signals in time so as to emulate substantially simultaneous receipt of the first and second signals in parallel.

14. A system according to claim 10, further comprising:
a trigger module coupled to the device under test and/or the signal analyser for providing a triggering signal to the processing resource and the device under test.

15. A system according to claim 10, further comprising:
a reference signal generator coupled to the first input port.

16. A method of testing a multi-port device under test, the method comprising:
receiving a first input signal at a common port via a first port over a first duration;
switching so as to receive a second input signal at the common port via a second port over a second duration; and
temporally arranging the first input signal and the second input signal.

17. A method according to claim 16, further comprising:
temporally arranging the first input signal and the second input signal in time so that the first and second input signals are arranged in time so as to emulate substantially simultaneous receipt of the first and second input signals in parallel.

18. A computer program element comprising computer program code means to make a computer execute the method according to claim 16.

19. A computer program element according to claim 18, embodied on a computer readable medium.
